(19) United States
(12) Patent Application Publication
(10) Pub. No.: US 2025/0218814 A1
(43) Pub. Date: Jul. 3, 2025

(54) SUBSTRATE PROCESSING APPARATUS AND SUBSTRATE PROCESSING METHOD

(71) Applicant: SEMES CO., LTD., Cheonan-sI (KR)

(72) Inventors: Myung A JEON, Yeosu-si (KR); Sul LEE, Cheonan-si (KR); Mi So PARK, Cheonan-si (KR); Ji Su HONG, Asan-si (KR); Bok Kyu LEE, Cheonan-si (KR)

(73) Assignee: SEMES CO., LTD., Cheonan-si (KR)

(21) Appl. No.: 19/005,201

(22) Filed: Dec. 30, 2024

(30) Foreign Application Priority Data
Dec. 28, 2023 (KR) 10-2023-0195366

(51) Int. Cl. H01L 21/67

(52) U.S. Cl. CPC H01L 21/67051; H01L 21/67253

(57) ABSTRACT

Disclosed are a substrate processing apparatus and a substrate processing method that are capable of detecting whether a treatment liquid has leaked from a nozzle and whether a temperature of the treatment liquid has reached a set temperature. The substrate processing apparatus includes: a housing providing an interior space; a support unit located in the interior space and supporting a substrate; a cup surrounding the support unit and having an open top; a liquid supply unit including a nozzle to supply a treatment liquid to the substrate supported by the support unit; and a waiting port which is installed in the housing and in which the nozzle waits, in which waiting port includes a liquid detection unit that detects a treatment liquid discharged from the nozzle while the nozzle is waiting.

### CROSS-REFERENCE TO RELATED APPLICATIONS

This application claims priority to and the benefit of Korean Patent Application No. 10-2023-0195366 filed in the Korean Intellectual Property Office on Dec. 28, 2023, the entire contents of which are incorporated herein by reference.

### TECHNICAL FIELD

The present invention relates to a substrate processing method and a substrate processing apparatus, and more specifically, to a substrate processing apparatus and a substrate processing method that are capable of detecting whether a treatment liquid has leaked from a nozzle and whether a temperature of the treatment liquid has reached a set temperature.

### BACKGROUND ART

In order to manufacture a semiconductor device, various processes, such as photography, deposition, ashing, etching, and ion implantation, are performed. In addition, before and after these processes are performed, a cleaning process is performed to clean the remaining particles on the substrate.

During the treatment of the substrate, the treatment liquid is supplied from the nozzle. When the substrate treatment is finished, the supply of the treatment liquid is stopped, and the nozzle moves to the waiting port and waits. The supply of the treatment liquid may be stopped by a valve. When the valve closing speed is high, the pressure of the pipe supplying the treatment liquid decreases and the treatment liquid remaining in the nozzle increases. This may prevent leakage of the treatment liquid from the nozzle.

However, due to defects in the valve, even when the valve is closed, the treatment liquid may not rise sufficiently or the waiting time may be prolonged, causing the treatment liquid to leak from the nozzle.

### SUMMARY OF THE INVENTION

The present invention has been made in an effort to provide a substrate processing apparatus and a substrate processing method capable of detecting whether a treatment liquid has leaked from a nozzle.

The present invention has also been made in an effort to provide a substrate processing apparatus and a substrate processing method that are capable of measuring a temperature of a discharged treatment liquid to detect whether the treatment liquid has reached a set temperature.

The problem to be solved by the present invention is not limited to the above-mentioned problems, and the problems not mentioned will be clearly understood by those skilled in the art from the descriptions below.

An exemplary embodiment of the present invention an apparatus of processing a substrate, the apparatus comprising: a housing providing an interior space; a support unit located in the interior space and supporting a substrate; a cup surrounding the support unit and having an open top; a liquid supply unit including a nozzle to supply a treatment liquid to the substrate supported by the support unit; and a waiting port which is installed in the housing and in which the nozzle waits, wherein the waiting port may include a liquid detection unit that detects a treatment liquid discharged from the nozzle while the nozzle is waiting.

According to the exemplary embodiment of the present invention the liquid detection unit detects whether the treatment liquid has leaked from the nozzle during a discharge stop period in which the discharge of the treatment liquid from the nozzle is stopped.

According to the exemplary embodiment of the present invention the liquid detection unit includes: a light emitting unit provided to emit light to a vertical downward path of an outlet of the nozzle while the nozzle waits at the waiting port; and a light receiving unit provided to receive the light emitted from the light emitting unit, and the liquid detection unit determines whether the treatment liquid may be leaked from the nozzle based on the amount of light received by the light receiving unit.

According to the exemplary embodiment of the present invention the liquid detection unit may include a camera provided to photograph an end of the nozzle or a vertical downward path of an outlet of the nozzle while the nozzle waits at the waiting port.

According to the exemplary embodiment of the present invention the treatment liquid is supplied to the nozzle in a heated state, and the camera may be a thermal imaging camera.

According to the exemplary embodiment of the present invention the treatment liquid is supplied to the nozzle in a heated state, and the liquid detection unit detects a temperature of the treatment liquid discharged from the nozzle.

According to the exemplary embodiment of the present invention the liquid detection unit may be a thermal imaging camera.

According to the exemplary embodiment of the present invention the liquid supply unit further includes a nozzle driver for moving the nozzle between the waiting port and the cup, the apparatus further includes a controller for controlling the nozzle driver, and when the liquid detection unit detects that a temperature of the treatment liquid discharged from the nozzle reaches a set temperature, the controller controls the nozzle driver to move the nozzle from the waiting port to the cup.

According to the exemplary embodiment of the present invention the apparatus may further include a heater for heating the treatment liquid before the treatment liquid is supplied to the nozzle, wherein the liquid detection unit includes a thermal imaging camera, and a temperature of the treatment liquid discharged from the nozzle and whether the treatment liquid leaks from the nozzle may be detected by an image photographed by the thermal imaging camera.

An exemplary embodiment of the present invention a method of processing a substrate, the method comprising: a substrate treatment operation of processing a substrate by supplying a treatment liquid to a nozzle supplying the treatment liquid; and a waiting operation in which the nozzle moves to a waiting port and waits at the waiting port, wherein the waiting operation is a leakage inspection operation of inspecting a discharge state of the treatment liquid discharged from the nozzle.

According to the exemplary embodiment of the present invention in the inspection operation, when the discharge of the treatment liquid from the nozzle is detected during a discharge stop period in which the discharge of the treatment liquid from the nozzle is stopped, it may be determined that the treatment liquid has leaked from the nozzle.

According to the exemplary embodiment of the present invention the inspection operation may include inspecting whether there is a leakage of the treatment liquid from the nozzle based on a light reception state of light emitted to an end of the nozzle or a movement path of the treatment liquid discharged from the nozzle while the nozzle is waiting at the waiting port.

According to the exemplary embodiment of the present invention the inspection operation may include photographing an end of the nozzle or a movement path of the treatment liquid discharged from the nozzle while the nozzle is waiting at the waiting port, and inspecting whether the treatment liquid leaks from the nozzle based on the photographed image.

According to the exemplary embodiment of the present invention the treatment liquid is supplied to the nozzle in a heated state, and the image may be acquired by a thermal imaging camera.

According to the exemplary embodiment of the present invention the treatment liquid is supplied in a heated state, before the nozzle is moved to a position where the substrate is treated, pre-dispensing is performed to discharge the treatment liquid from the nozzle at the waiting port, and the method further may include a temperature detection operation of measuring a temperature of the treatment liquid discharged from the nozzle during the pre-dispensing to detect whether the temperature has been reached a set temperature.

According to the exemplary embodiment of the present invention when the temperature of the treatment liquid reaches the set temperature, the nozzle may be moved to a position where the substrate is treated.

An exemplary embodiment of the present invention a method of processing a substrate, the method comprising: a waiting operation in which a nozzle waits at a waiting port; and a treatment operation of processing a substrate by supplying a heated treatment liquid to the substrate, wherein pre-dispensing is performed to discharge the heated treatment liquid to the waiting port before the nozzle moves from the waiting port to a position for processing the substrate, and
a temperature detection operation of detecting a temperature of the treatment liquid discharged from the nozzle during the pre-dispensing, and determining whether the treatment liquid has reached the set temperature may be performed.

According to the exemplary embodiment of the present invention the detection of the temperature of the treatment liquid may be based on the image acquired by a thermal imaging camera.

According to the exemplary embodiment of the present invention the apparatus may further include during the waiting operation, a leakage inspection operation of detecting whether the heated treatment liquid leaks from the nozzle by using the thermal imaging camera.

According to the exemplary embodiment of the present invention when the temperature of the treatment liquid reaches the set temperature, the nozzle is moved to a position where the substrate may be treated.

According to the present invention, the present invention may detect whether a treatment liquid has leaked from a nozzle.

In addition, the present invention may detect whether the treatment liquid has reached a set temperature by measuring a temperature of the discharged treatment liquid.

The effects of the invention are not limited to those described above, and those not described will be apparent to those skilled in the art from this specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view schematically illustrating a substrate processing apparatus according to an exemplary embodiment of the present invention.

FIG. 2 is a diagram schematically illustrating an exemplary embodiment of a liquid processing chamber of FIG. 1.

FIG. 3 is a diagram illustrating a shape of a waiting port including a liquid detection unit according to the exemplary embodiment of the present invention.

FIGS. 4a and 4b are diagrams illustrating a state of determining whether a treatment liquid is leaked by using a light emitting unit and a light receiving unit.

FIG. 5 is a diagram illustrating an appearance of a waiting port including a liquid detection unit according to another exemplary embodiment of the present invention.

FIG. 6 is a diagram illustrating a state in which leakage is detected by using the liquid detection unit of FIG. 5.

FIG. 7 is a flowchart illustrating a substrate processing method according to an exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as a target to be treated. However, the technical spirit of the present invention may be applied to devices used for processing other types of substrates other than wafers as treatment targets.

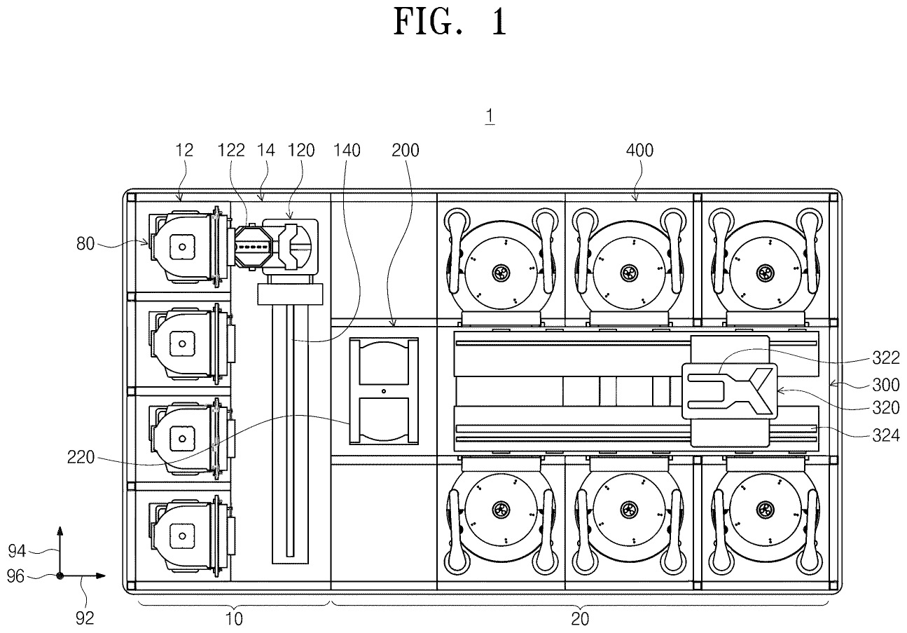

Hereinafter, an exemplary embodiment of the present invention will be described with reference to the accompanying drawings. FIG. 1 is a top plan view schematically illustrating a substrate processing apparatus according to an exemplary embodiment of the present invention.

Referring to FIG. 1, the substrate processing apparatus includes an index module 10, a processing module 20, and a controller 30. According to the exemplary embodiment, the index module 10 and the processing module 20 are disposed along one direction. Hereinafter, the direction in which the index module 10 and the processing module 20 are arranged is referred to as a first direction 92, a direction perpendicular to the first direction 92 when viewed from the top is referred to as a second direction 94, and a direction perpendicular to both the first direction 92 and the second direction 94 is referred to as a third direction 96.

The index module 10 transfers the substrate W from a container 80 in which the substrate W is received to the processing module 20, and receives the substrate W treated by the processing module 20 to the container 80. A longitudinal direction of the index module 10 is provided in the second direction 94. The index module 10 includes a load port 12 and an index frame 14. With respect to the index frame 14, the load port 12 is located at a side opposite to the processing module 20. The containers 80 in which the substrates W are received are placed on the load ports 12. A plurality of load ports 12 may be provided, and a plurality of load ports 12 may be disposed along the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 having a longitudinal direction provided in the second direction 94 is provided in the index frame 14, and the index robot 120 may be provided to be movable on the guide rail 140. The index robot 120 includes a hand 122 on which the substrate W is placed, and the hand 122 may be provided to be movably forwardly and backwardly, rotatable around the third direction 96 and movable along the third direction 96. A plurality of hands 322 are provided to be spaced apart in the vertical direction, and the hands 322 may move forward and backward independently of each other.

The processing module 20 includes a buffer chamber 200, a transfer chamber 300, and a processing chamber 400. The buffer chamber 200 provides a space in which the substrate W loaded into the processing module 20 and the substrate W unloaded from the processing module 20 temporarily stay. The treatment chamber 400 performs a treatment process for liquid-treating the substrate W by supplying a liquid onto the substrate W. The transfer chamber 300 transfers the substrate W between the buffer unit 200 and the liquid processing chamber 400.

A longitudinal direction of the transfer chamber 300 may be provided in the first direction 92. The buffer chamber 200 may be disposed between the index module 10 and the transfer chamber 300. A plurality of liquid treatment chambers 400 may be provided and may be disposed at a side portion of the transfer chamber 300. The liquid treatment chamber 400 and the transfer chamber 300 may be disposed along the second direction 94. The buffer chamber 200 may be positioned at one end of the transfer chamber 300.

According to the example, the liquid processing chambers 400 are respectively disposed on both sides of the transfer chamber 300. At one side of the transfer device 300, the liquid processing devices 400 may be provided in an arrangement of A×B (each of A and B is 1 or a natural larger than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. A plurality of hands 322 are provided to be spaced apart in the vertical direction, and the hands 322 may move forward and backward independently of each other.

The buffer chamber 200 includes a plurality of buffers 220 on which the substrate W is temporarily placed. The buffers 220 may be disposed to be spaced apart from each other along the third direction 96. A front face and a rear face of the buffer unit 200 are opened. The front face is a face facing the index module 10, and the rear face is a face facing the transfer chamber 300. The index robot 120 may access the buffer chamber 200 through the front face, and the transfer robot 320 may access the buffer chamber 200 through the rear face.

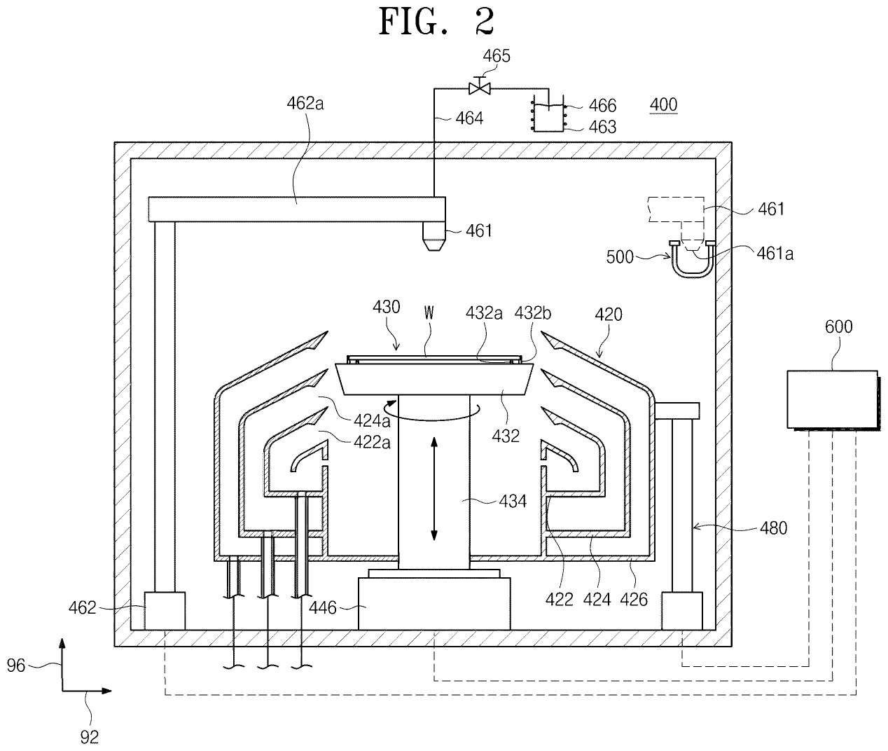

FIG. 2 is a diagram schematically illustrating an exemplary embodiment of the liquid processing chamber 400 of FIG. 1. Referring to FIG. 2, the liquid treatment chamber 400 includes a housing 410, a cup body 420, a support unit 430, a lifting unit 450, a liquid supply unit 460, a waiting port 500, and a controller 600.

The housing 410 is provided in a generally rectangular parallelepiped shape. The cup body 420, the support unit 430, and the liquid supply unit 440 are disposed within the housing 410.

The cup body 420 has a treatment space with an open top, and the substrate W is liquid-treated in the treatment space. The support unit 430 supports the substrate W in the treatment space. The liquid supply unit 440 supplies the liquid onto the substrate W supported by the support unit 430. The liquid may be provided in a plurality of types, and may be sequentially supplied onto the substrate W. The lifting unit 450 adjusts a relative height between the cup body 420 and the support unit 430.

According to the example, the cup body 420 includes a plurality of cups 422, 424, and 426. Each of the cups 422, 424, and 426 has a recovery space of recovering the liquid used for the treatment of the substrate. Each of the cups 422, 424, and 426 is provided in a ring shape surrounding the support unit 430. When the liquid treatment process is in progress, the treatment liquid scattered by the rotation of the substrate W is introduced into the recovery space through inlets 422a, 424a, and 426a of the respective cups 422, 424, and 426. According to the example, the cup 420 includes a first cup 422, a second cup 424, and a third cup 426. The first cup 422 is disposed to surround the support unit 430, the second cup 424 is disposed to surround the first cup 422, and the third cup 426 is disposed to surround the second cup 424. A second inlet 424a, which introduces the liquid into the second cup 424, may be positioned above a first inlet 422a, which introduces the liquid into the first cup 422, and a third inlet 426a, which introduces the liquid into the third cup 426, may be positioned above the second inlet 424a.

The support unit 430 includes a support plate 432 and a driving shaft 434. An upper surface of the support plate 432 may be provided in a generally circular shape, and may have a diameter larger than a diameter of the substrate W. In the center portion of the support plate 432, a support pin 432a is provided to support the rear face of the substrate W, and the support pin 432a is provided with its upper end protruding from the support plate 432 so that the substrate W is spaced apart from the support plate 432 by a certain distance. A chuck pin 432b is provided to an edge of the support plate 432. The chuck pin 432b is provided to protrude upwardly from the support plate 432, and supports the side portion of the substrate W so that the substrate W is not separated from the support unit 430 when the substrate W is rotated. The driving shaft 434 is driven by a driver 436, is connected to the center of the bottom surface of the substrate W, and rotates the support plate 432 with respect to the central axis thereof.

The lifting unit 450 moves the cup body 420 in the up and down direction. By the up and down movement of the cup body 420, a relative height between the cup body 420 and the substrate W is changed. Accordingly, since the cups 422, 424, and 426 for recovering the treatment liquid are changed according to the type of the liquid supplied to the substrate W, the liquids may be separated and recovered. Unlike the description, the cup body 420 may be fixedly installed, and the lifting unit 480 may move the support unit 440 in the vertical direction.

The liquid supply unit 460 supplies the treatment liquid onto the substrate W. The liquid supply unit 460 includes a nozzle 461, a nozzle driver 462, a treatment liquid supply source 463, a treatment liquid supply line 464, a valve 465, and a heater 466.

The nozzle 461 supplies the treatment liquid onto the substrate W. The treatment liquid may be a liquid having a temperature higher than room temperature. According to the exemplary embodiment, the treatment liquid may be an acidic solution. The nozzle 461 has a flow path 461b through which a treatment liquid passes. The flow path 461b may be formed perpendicular to a surface of a nozzle end 461a.

The nozzle driver 462 moves the nozzle 461 between the waiting port 500 and the cup body 420. The nozzle 461 is supported by the arm 462a.

Optionally, the liquid supply unit 460 may further include one or more nozzles in addition to the nozzle 461. Additional nozzles may supply different types of treatment liquids to the substrate. For example, the other type of treatment liquid may be an acid solution or a base solution for removing foreign substances on the substrate. In addition, another type of treatment liquid may be alcohol having surface tension lower than that of water. For example, the alcohol may be isopropyl alcohol. The nozzle 461 and the added nozzle are supported on different arms, respectively, and these arms may be moved independently. Optionally, the nozzle 461 and the nozzle added may be mounted on the same arm and moved simultaneously.

The treatment liquid supply source 463 stores and supplies the treatment liquid. A plurality of treatment liquid supply sources 463 may be provided depending on the type of treatment liquid. The treatment liquid supply line 464 connects the treatment liquid supply source 463 and the nozzle 461. The valve 465 is installed on the treatment liquid supply line 464. The valve 465 opens and closes the treatment liquid supply line 464. The opening and closing speed of the valve 465 is adjusted. As the closing speed of the valve 465 increases, the treatment liquid supply line 464 is depressurized, and the supply of the treatment liquid may be stopped while rising in the nozzle 461. Accordingly, the heater 465 heats the treatment liquid to prevent the treatment liquid from leaking from the nozzle 461. The heater 465 may be installed on the treatment liquid supply source 463. Furthermore, the heater 465 may be installed on the treatment liquid supply line 464.

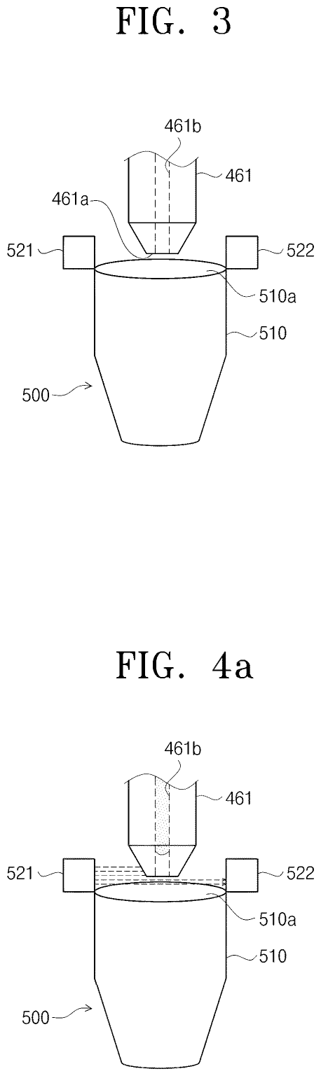

FIG. 3 is a diagram illustrating a shape of the waiting port including a liquid detection unit according to the exemplary embodiment of the present invention. Referring to FIG. 4, the waiting port 500 is installed outside the cup body 420. The waiting port 500 may be provided on a sidewall of the housing 410. The waiting port 500 provides a waiting space in which the nozzle 461 waits. The waiting port 500 includes a body 510 and a liquid detection unit 520.

The body 510 provides a discharge space. The body 510 has an opening 510a in an upper portion thereof. The nozzle 461 may be located on the opening 510a. The nozzle 461 may stand by in the opening 510a and discharge the treatment liquid into the discharge space.

The liquid detection unit 520 detects whether the treatment liquid is leaked from the nozzle 461. The liquid detection unit 520 detects the end 461a of the nozzle. The liquid detection unit 520 detects a movement path of the treatment liquid. When the treatment liquid is detected, the liquid detection unit 520 may determine that the treatment liquid leaks.

The liquid detection unit 520 may include a light emitting unit 521 and a light receiving unit 522. The light emitting unit 521 emits light toward a movement path of the treatment liquid. The light receiving unit 522 receives the light emitted from the light emitting unit 521. The light receiving unit 522 may measure the amount of received light. It is possible to determine whether the treatment liquid is leaked or not based on the amount of light emitted to the light receiving unit 522.

FIGS. 4a and 4b are diagrams illustrating a state of determining whether a treatment liquid is leaked by using the light emitting unit and the light receiving unit. When there is no leakage of the treatment liquid from the nozzle 461, the amount of light received by the light receiving unit 522 is constant as illustrated in FIG. 4a. When there is a leakage of the treatment liquid from the nozzle 461, the amount of light received by the light receiving unit 522 changes as illustrated in FIG. 4b. Some of the light emitted by the light emitting unit 521 meets the treatment liquid and changes a path. Accordingly, the amount of light received by the light receiving unit 522 is reduced, and it is possible to detect that the treatment liquid has leaked.

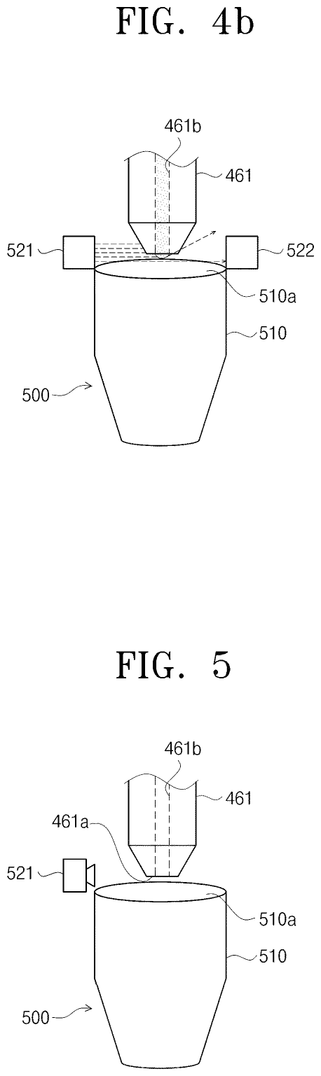

FIG. 5 is a diagram illustrating an appearance of a waiting port including a liquid detection unit according to another exemplary embodiment of the present invention, and FIG. 6 is a diagram illustrating a state in which leakage is detected by using the liquid detection unit of FIG. 5. Referring to FIGS. 5 and 6, the liquid detection unit 520 may measure the temperature of the end 461a of the nozzle. In addition, the liquid detection unit 520 may measure the temperature of the treatment liquid present on the movement path of the treatment liquid. According to an example, the liquid detection unit 520 may be a temperature sensor 523. According to an example, the temperature sensor 523 may be a thermal imaging camera. The treatment liquid may be heated to a high temperature by the heater 465. When the high-temperature treatment liquid leaks from the nozzle 461, the liquid detection unit 520 may detect a high temperature and detect that the treatment liquid has leaked. In addition, when the high-temperature treatment liquid is supplied onto the substrate W, the treatment liquid is discharged in advance (pre-dispensing) from the waiting port 500, and the temperature sensor 523 may detect whether the treatment liquid has reached a set temperature.

The controller 600 controls the liquid supply unit 460 and the liquid detection unit 520. Hereinafter, a method of processing a substrate by using the controller 600 will be described.

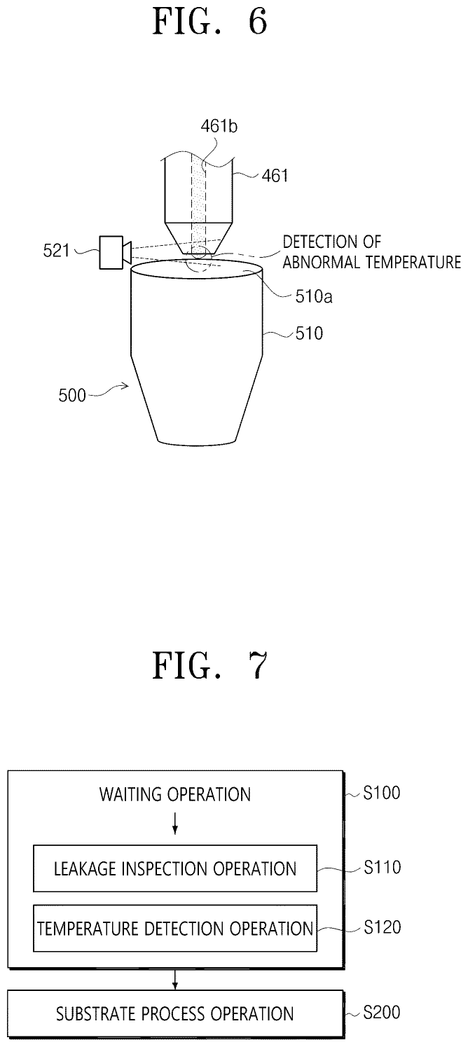

FIG. 7 is a flowchart illustrating a substrate processing method according to an exemplary embodiment of the present invention. Referring to FIG. 6, the substrate processing method may include a waiting operation S100 and a substrate treatment operation S200.

The waiting operation S100 is an operation in which the nozzle 461 waits in the waiting port 500. The nozzle 461 moves to the waiting port 500. The nozzle 461 is located on the opening 510a. During the waiting operation S100, the controller 600 may instruct whether to discharge the treatment liquid. During the waiting operation S100, a leakage inspection operation S110 and a temperature detection operation S120 may be performed.

The leakage inspection operation S110 is an operation of inspecting whether the treatment liquid leaks from the end 461a of the nozzle. When there is no instruction to discharge the treatment liquid from the controller 500, the liquid detection unit 520 detects whether the treatment liquid is leaked from the end 461a of the nozzle. When leakage of the treatment liquid is detected by the liquid detection unit 520, the controller 600 may generate an alarm. The liquid detection unit 520 detects whether the treatment liquid is leaked by using the light emitting unit 521 and the light receiving unit 522. The light emitting unit 521 emits light on the movement path of the treatment liquid, and the light receiving unit determines whether the treatment liquid is leaked based on the amount of light received. Alternatively, the liquid detection unit 520 detects whether the treatment liquid is leaked by measuring the temperature of the end 461a of the nozzle or the treatment liquid movement path. When the liquid detection unit 520 includes a thermal imaging camera, the liquid detection unit 520 determines whether the treatment liquid is leaked through the photographed image.

The temperature detection operation S120 is an operation of measuring the temperature of the treatment liquid. The liquid detection unit 520 measures the temperature of the treatment liquid discharged during pre-dispensing. Pre-dispensing means discharging the treatment liquid to the waiting port 500 before processing the substrate W. When the liquid detection unit 520 includes a thermal imaging camera, the liquid detection unit 520 may measure the temperature of the treatment liquid through a photographed image. When the treatment liquid needs to be heated to a set temperature, the liquid detection unit 520 may determine whether the treatment liquid has reached a set temperature. In addition, when the temperature drops while the treatment liquid remaining in the nozzle remains for a long time, the liquid detection unit 520 may check whether or not the low-temperature treatment liquid has been fully discharged. Thereafter, when it is determined that the temperature of the treatment liquid reaches the set temperature, the controller 600 may move the nozzle 461 onto the substrate W and control the substrate W to be treated.

The substrate treatment operation S200 is an operation of processing the substrate W by supplying a treatment liquid. In the substrate treatment operation S200, the nozzle 461 moves onto the substrate W. The nozzle 461 discharges the treatment liquid. The treatment liquid may be at a high temperature. When the substrate treatment operation S200 is terminated, the valve 465 is closed, and the treatment liquid remaining inside the nozzle 461 rises upwardly. Thereafter, the waiting operation S100 may be performed again.

According to the exemplary embodiment of the present invention, it is possible to detect whether leakage of the treatment liquid has occurred in the nozzle. Accordingly, it is possible to prevent the nozzle from being contaminated by the treatment liquid.

In addition, by measuring the temperature of the treatment liquid from the nozzle, it is possible to detect whether the high-temperature treatment liquid leaks and determine whether the treatment liquid has reached a set temperature.

In the above-described example, the present invention has been described based on the case where the treatment liquid stored in the supply tank 1200 is an aqueous phosphoric acid solution as an example. However, unlike this, the treatment liquid stored in the supply tank 1200 may be another type of treatment liquid that includes water and adjusts the concentration by evaporation of water.

In addition, in the above-described example, the present invention has been described based on the case where both the leakage inspection operation S110 and the temperature detection operation S120 are performed as an example. However, it is not limited to this, and only one may be performed.

In addition, in the above-described example, the present invention has been described based on the case where the high-temperature treatment liquid is supplied as an example. However, the present invention is not limited thereto, and a low-temperature or room-temperature treatment liquid may be supplied.

The foregoing detailed description illustrates the present invention. In addition, the above description represents and describes exemplary embodiments of the present invention, which may be used in a variety of other combinations, changes, and environments. This means that changes or modifications may be made to the scope of the concepts of the invention disclosed herein, to the extent that they are equivalent to the original invention, and/or to the extent of the skill or knowledge in the art. The disclosed exemplary embodiments describe the best state of the art for implementing the technical spirits of the invention, and various changes are possible as required by specific applications and uses of the invention. Accordingly, the foregoing detailed description of the invention is not intended to limit the invention to the disclosed exemplary embodiments. Further, the accompanying claims should be construed to include other exemplary embodiments as well.

1. An apparatus of processing a substrate, the apparatus comprising:
a housing providing an interior space;
a support unit located in the interior space and supporting a substrate;
a cup surrounding the support unit and having an open top;
a liquid supply unit including a nozzle to supply a treatment liquid to the substrate supported by the support unit; and
a waiting port which is installed in the housing and in which the nozzle waits,
wherein the waiting port includes a liquid detection unit that detects a treatment liquid discharged from the nozzle while the nozzle is waiting.

2. The apparatus of claim 1, wherein the liquid detection unit detects whether the treatment liquid has leaked from the nozzle during a discharge stop period in which the discharge of the treatment liquid from the nozzle is stopped.

3. The apparatus of claim 2, wherein the liquid detection unit includes:
a light emitting unit provided to emit light to a vertical downward path of an outlet of the nozzle while the nozzle waits at the waiting port; and
a light receiving unit provided to receive the light emitted from the light emitting unit, and
the liquid detection unit determines whether the treatment liquid is leaked from the nozzle based on the amount of light received by the light receiving unit.

4. The apparatus of claim 2, wherein the liquid detection unit includes a camera provided to photograph an end of the nozzle or a vertical downward path of an outlet of the nozzle while the nozzle waits at the waiting port.

5. The apparatus of claim 4, wherein the treatment liquid is supplied to the nozzle in a heated state, and
the camera is a thermal imaging camera.

6. The apparatus of claim 1, wherein the treatment liquid is supplied to the nozzle in a heated state, and
the liquid detection unit detects a temperature of the treatment liquid discharged from the nozzle.

7. The apparatus of claim 6, wherein the liquid detection unit is a thermal imaging camera.

8. The apparatus of claim 1, wherein the liquid supply unit further includes a nozzle driver for moving the nozzle between the waiting port and the cup,
the apparatus further includes a controller for controlling the nozzle driver, and
when the liquid detection unit detects that a temperature of the treatment liquid discharged from the nozzle reaches a set temperature, the controller controls the nozzle driver to move the nozzle from the waiting port to the cup.

9. The apparatus of claim 1, further comprising:
a heater for heating the treatment liquid before the treatment liquid is supplied to the nozzle,
wherein the liquid detection unit includes a thermal imaging camera, and
a temperature of the treatment liquid discharged from the nozzle and whether the treatment liquid leaks from the nozzle are detected by an image photographed by the thermal imaging camera.

10.-20. (canceled)
